(19) United States
(12) Patent Application Publication
(10) Pub. No.: US 2009/0315109 A1
(43) Pub. Date: Dec. 24, 2009

(54) SEMICONDUCTOR DEVICE HAVING OTP CELLS AND METHOD FOR FABRICATING THE SAME

(76) Inventor: Min-Seok Kim, Gangnam-gu (KR)

Correspondence Address: SHERR & VAUGHN, PLLC, 620 HERNDON PARKWAY, SUITE 320, HERNDON, VA, 20170, US

(21) Appl. No.: 12/484,305

(22) Filed: Jun. 15, 2009

(30) Foreign Application Priority Data
Jun. 20, 2008 (KR) 2008-0058224

(51) Int. Cl. H01L 29/78; H01L 21/336; H01L 21/02; H01L 23/525

(52) U.S. Cl. 257/343; 438/238; 257/E29.261; 257/E21.417; 257/E21.004; 257/E23.147

(57) ABSTRACT

A semiconductor device includes a deep N-type well region which may be formed by applying an ion-implantation process, using a mask, to a predetermined pattern over a portion of a semiconductor substrate over which an oxide film is formed, a dwell region which may be formed by applying an ion-implantation process, using a mask, to a predetermined pattern over a portion of the N-type well region, a shallow N-type well region and a drain region which may be respectively formed by applying an ion-implantation process, using a mask, to a predetermined pattern over a portion of the deep N-type well region, a source region which may be formed by applying an ion-implantation process, using a mask, to a predetermined pattern over a portion of the dwell region, a contact hole which may be formed by being filled with a metal after forming an inter-metal dielectric layer over a portion of the semiconductor substrate over which the source region is formed, and a metal line formed over a portion of the contact hole.

The present application claims priority under 35 U.S.C. 119 to Korean Patent Application No. 10-2008-0058224 (filed on Jun. 20, 2008), which is hereby incorporated by reference in its entirety.

### BACKGROUND

The present invention relates generally to a device having One Time Programmable cells, and more particularly to a semiconductor device having One Time Programmable cells formed using a Lateral Double Diffused Metal Oxide Semiconductor technology, and a method for fabricating the same.

A One Time Programmable (OTP) cell may be used for storing program codes and other information. OTP cells include a one-time programmable feature which can prevent abnormal overwrite or modification of stored program codes and other information. A OTP cell may be fabricated using, for example, a fusible link, a floating gate non-volatile memory, or an antifuse technology.

Fabricating a antifused-type OTP cell requires the physical destruction or rupture of a portion of a Metal Oxide Semiconductor (MOS) capacitor gate oxide dielectric. Destruction or rupture of an oxide dielectric may be accomplished by applying a high voltage to a MOS capacitor, which forms a relatively low electric resistance conductive passage in the oxide dielectric between capacitor plates. Because a antifused-type OTP cell requires a relatively high voltage for programming, it is not as practical compared to a Complementary Metal Oxide Semiconductor (CMOS) technology. However, a CMOS technology exhibits comparatively low reliability as its relatively thin MOS gate oxide prevents reliable programming.

Related OTP cells suffer from further drawbacks, including an inability to bear a high programming voltage and comparatively higher sensitivity to a short pulse of high current. Also, because a transistor is required in a semiconductor to prevent electrostatic discharge (ESD) resulting from high voltage programming, related OTP cells suffer from the drawback of increased cell size and area. Accordingly, there is a need for an improved OTP cell and a method of fabricating the same.

### SUMMARY

According to embodiments, a semiconductor device includes a deep N-type well region, which may be formed by applying an ion-implantation process, using a mask, to a predetermined pattern over a portion of a semiconductor substrate over which an oxide film is formed, a dwell region, which may be formed by applying an ion-implantation process, using a mask, to a predetermined pattern over a portion of the N-type well region, a shallow N-type well region and a drain region which may be respectively formed by applying an ion-implantation process, using a mask, to a predetermined pattern over a portion of the deep N-type well region, a source region, which may be formed by applying an ion-implantation process, using a mask, to a predetermined pattern over a portion of the dwell region, a contact hole, which may be formed by being filled with a metal after forming an inter-metal dielectric layer over a portion of the semiconductor substrate over which the source region is formed, and a metal line, which may be formed over a portion of the contact hole.

According to embodiments, a method of fabricating a OTP cell for a semiconductor device includes forming a deep N-type well region by applying an ion-implantation process, using a mask, to a predetermined pattern over a portion of a semiconductor substrate over which an oxide film is formed, forming a dwell region by applying an ion-implantation process, using a mask, to a predetermined pattern over a portion of the deep N-type well region, forming a shallow N-type well region and a drain region by applying an ion-implantation process, using a mask, to a predetermined pattern over a portion of the deep N-type well region, forming a source region by applying an ion-implantation process, using a mask, to a predetermined pattern over a portion of the dwell region, forming a contact hole filled with a metal after forming an inter-metal dielectric layer over a portion of the semiconductor substrate, and forming a metal line over a portion of the contact hole.

### DRAWINGS

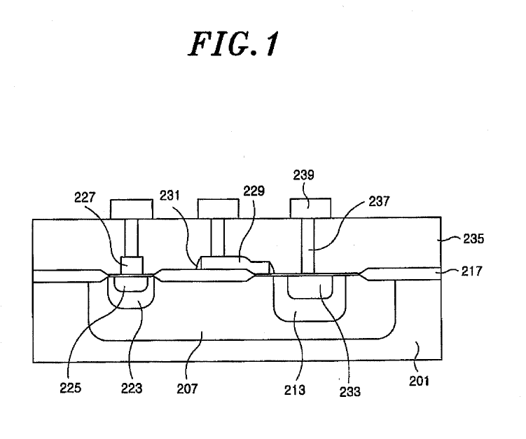

Example FIG. 1 is a schematic cross sectional view illustrating a semiconductor device including an OTP cell according to embodiments.

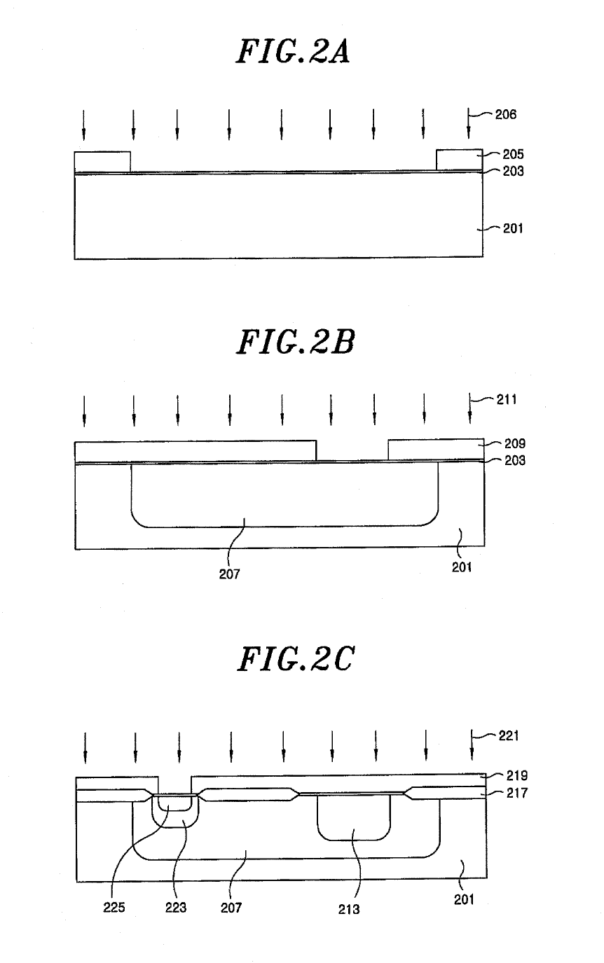

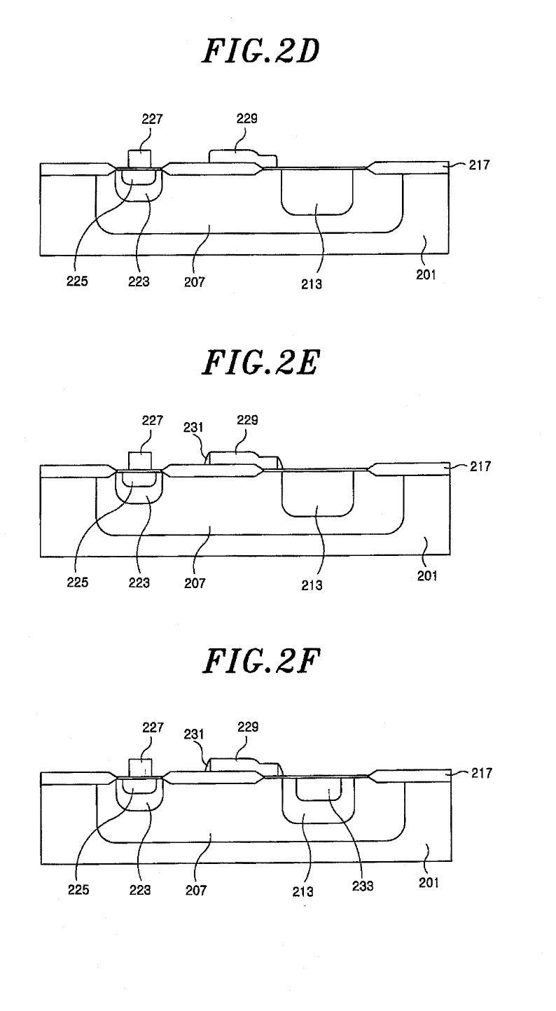

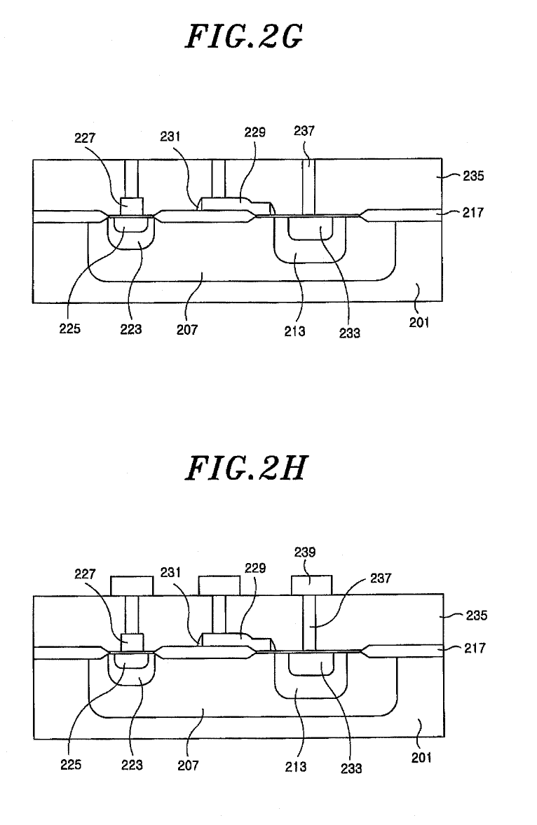

Examples FIG. 2A to FIG. 2H are schematic cross sectional views showing steps of fabricating an OTP cell of a semiconductor device according to embodiments.

### DESCRIPTION

Hereinafter, embodiments will be described in detail with reference to the accompanying drawings. Example FIG. 1 is a schematic cross sectional view illustrating a semiconductor device including an OTP cell according to embodiments. Referring to example FIG. 1, a semiconductor device includes a deep N-type well (DeepNWell) region 207, which may be formed by applying an ion-implantation process, using a mask, to a predetermined pattern over a portion of a semiconductor substrate 201, and includes a dwell (DWell) region 213, which may be formed by applying an ion-implantation process, using a mask, to a predetermined pattern over a portion of the deep N-type well region 207. An oxide film pattern 217 is shown, and may be formed by applying a photolithography process to an oxide film formed over a portion of the semiconductor substrate 201. Example FIG. 1 also shows a shallow N-type well region 223 and a drain region 225, which may be respectively formed by applying an ion-implantation process twice at relatively different doses, using a mask, to a predetermined pattern over a portion of the deep N-type well region 207.

Referring again to example FIG. 1, an antifused poly pattern 227 and a gate poly pattern 229 are shown, which may be formed by applying a photolithography process to a gate oxide film formed over a portion of the semiconductor substrate 201. Example FIG. 1 shows a sidewall spacer 231 which, in embodiments, may be formed over a portion of side walls of the gate poly pattern 229 by etching an insulation material, formed thereover, with a predetermined pattern mask. A source region 233 is shown in example FIG. 1, which may be formed by applying an ion-implantation process, using a mask, to a predetermined pattern over a portion of the dwell region 213, and a contact hole 237 is also shown in example FIG. 1, which may be formed by making a contact hole region in an inter-metal dielectric layer 235, filling the contact hole region with a metal, and globally planarizing the metal. Example FIG. 1 shows a metal line 239, which may be formed over a portion, that may include an upper portion, of the globally planarized contact hole 237.

Examples FIG. 2A to FIG. 2H are schematic cross sectional views showing steps of fabricating a OTP cell of a semiconductor device according to embodiments. Referring to example FIG. 2A, an oxide film 203 may be formed over a portion of a semiconductor substrate 201, such as a silicon substrate, a ceramic substrate, or a polymer substrate. According to embodiments, a light exposure process and a developing process using a reticle design, to have a desired pattern, may be applied over the oxide film 203 to selectively remove parts of a photo resist (PR) formed over a portion of the semiconductor substrate 201. As a result, a first PR pattern 205 may be fabricated over a portion of the oxide film 203 that may indicate an ion-implantation region for a deep N-type well.

Referring to example FIG. 2B, an ion-implantation process 206 may be applied, using a mask, to the first PR pattern 205 such that a deep N-type well region 207 may be formed. In embodiments, a light exposure process and a developing process may selectively remove parts of a PR formed over a portion of the semiconductor substrate 201. As a result, a second PR pattern 209 may be fabricated over a portion of the oxide film 203 that may indicate a dwell ion-implantation region. According to embodiments, an ion-implantation process 211 may be applied using a mask to the second PR pattern 209. In embodiments, a boron dopant may be used, at a dose of approximately 10¹² to 10¹⁴and a ion-implantation energy at approximately 40 KeV to 60 KeV.

Referring to example FIG. 2C, dwell region 213 may be formed in a portion of the deep N-type well region 207. In embodiments, an oxide film pattern 217 may be formed by performing a photolithography process for the oxide film 203 formed over a portion of the semiconductor substrate 201. According to embodiments, a light exposure process and a developing process may be applied to selectively remove parts of the PR formed over a portion of the semiconductor substrate 201. As a result, a third PR pattern 219 may be fabricated over a portion of the oxide film 203 and the oxide film pattern 217 that may indicate ion-implantation regions for a shallow N-type well and a drain. In embodiments, an ion-implantation process 221 may be applied, using a mask, to the third PR pattern 219, twice, at different and relatively low doses. According to embodiments, a phosphorous dopant may be used selectively for each process. As a result, a shallow N-type well region 223 and a drain region 225 may be fabricated.

Referring to example FIG. 2D, an antifused poly pattern 227 and a gate poly pattern 229 may be fabricated by performing a photolithogrphy process for a gate oxide film formed over a portion of the semiconductor substrate 201. An antifuse of the antifused poly pattern 227 may be broken down into a resistor by a high voltage and a short pulse of a high current that are supplied during programming by a drain, such that the device may be turned on at a relatively low voltage.

Referring to example FIG. 2E, a sidewall spacer 231 may be formed over a portion of the side walls of the gate poly pattern 229 by etching an insulation material, such as a silicon oxide (SiO₂) film formed over the gate poly pattern 229, with a predetermined pattern mask. In embodiments, a dry etching process may be used.

Referring to example FIG. 2F, a fourth PR pattern may be formed according to embodiments which may indicate an ion-implantation region for a source, and an ion-implantation process may be applied, using a mask, to the fourth PR pattern such that a source region 233 may be formed in the dwell region 213. In embodiments, an arsenic dopant may be used.

Referring to example FIG. 2G, an inter-metal dielectric layer 235 may be formed over a portion of the semiconductor substrate 201, and a contact hole region may be formed therein. A metal may be filled in the contact hole region, and a chemical mechanical polishing (CPM) process may be applied to the filled contact hole region, thereby fabricating a globally planarized contact hole 237. Referring to FIG. 2H, a metal line 239 may be formed as an interconnect metal over a portion, which may be an upper portion, of the globally planarized contact hole 237.

According to embodiments, an OTP cell fabricated using a LDMOS structure can bear against a high voltage and is not affected by a short pulse of a high current during operation. In addition, the reliability of a device is secured by removing any effect from ESD during high voltage programming, and a uniform voltage is guaranteed by forming a source and a channel via a double diffused well, thereby making a device more stable in its electric operation. Further, a high voltage and a short pulse of a high current are supplied only when a device is programmed by a drain, breaking an antifuse down into resistor, and allowing for a lower voltage supply to turn the device on thereby reducing the device power consumption. Also, a minimum cell area is realized.

It will be obvious and apparent to those skilled in the art that various modifications and variations can be made in embodiments disclosed. Thus, it is intended that the disclosed embodiments cover the obvious and apparent modifications and variations, provided that they are within the scope of the appended claims and their equivalents.

What is claimed is:

1. An apparatus comprising:
a deep N-type well region formed in a portion of a semiconductor substrate over which an oxide film is formed;
a dwell region formed in a portion of the deep N-type well region;
a shallow N-type well region formed in a portion of the deep N-type well region;
a drain region formed in a portion of the shallow N-type well region;
a source region formed in a portion of the dwell region;
a contact hole formed in a portion of an inter metal dielectric layer formed over the semiconductor substrate over which the source region is formed; and
a metal line formed over a portion of the contact hole.

2. The apparatus of claim 1, wherein the semiconductor substrate comprises at least one of a silicon substrate, a ceramic substrate, and a polymer substrate.

3. The apparatus of claim 1 comprising:
an oxide film pattern formed of the oxide film;
an antifused poly pattern; and
a gate poly pattern,
wherein at least one of the antifused poly pattern and the gate poly pattern are formed of a gate oxide film that is formed over a portion of the semiconductor substrate over which the shallow N-type well region and the drain region are formed.

4. The apparatus of claim 3, wherein an antifuse of the antifused poly pattern may be broken down into a resistor.

5. The apparatus of claim 4, wherein the antifuse may be broken down into a resistor during programming of the apparatus by a drain.

6. The apparatus of claim 4, wherein the apparatus is turned on at a relatively low voltage.

7. The apparatus of claim 3, wherein a sidewall spacer is formed over a portion of a side wall of the gate poly pattern.

8. A method comprising:
forming a deep N-type well region in a portion of a semiconductor substrate over which an oxide film is formed;
forming a dwell region in a portion of the deep N-type well region;
forming a shallow N-type well region in a portion of the deep N-type well region;
forming a drain region in a portion of the shallow N-type well region;
forming a source region in a portion of the dwell region;
forming a contact hole filled with a metal in an inter metal dielectric layer formed over a portion of the semiconductor substrate; and
forming a metal line on a portion of the contact hole.

9. The method of claim 8, wherein the forming of at least one of the deep N-type well region, the dwell region, the shallow N-type well region, the drain region, and the source region comprises applying an ion-implantation process.

10. The method of claim 9, wherein the at least one ion implantation processes comprises using a mask.

11. The method of claim 10, wherein the at least one ion-implantation process is applied to a predetermined pattern.

12. The method of claim 9, wherein the shallow N-type well region and the drain region are respectively formed by applying the at least one ion-implantation process twice at different relatively low doses with a phosphorous dopant selectively used for each process.

13. The method of claim 8 comprising:
forming an oxide film pattern of the oxide film;
forming an antifused poly pattern; and
forming a gate poly pattern,
wherein at least on of the antifused poly pattern and the gate poly pattern are formed of a gate oxide film that is formed over a portion of the semiconductor substrate over which the shallow N-type well region and the drain region are formed.

14. The method of claim 13, wherein the forming of at least one of the oxide film pattern, the antifused poly pattern, and the gate poly pattern comprises performing a photolithography process.

15. The method of claim 13, comprising forming a sidewall spacer on a portion of a side wall of the gate poly pattern.

16. The method of claim 15, wherein the sidewall spacer is formed by etching an insulation material disposed over the gate poly pattern using a predetermined pattern mask.

17. The method of claim 13, wherein an antifuse of the antifused poly pattern is broken down into a resistor.

18. The method of claim 17, wherein the antifuse is broken down into a resistor by supplying a high voltage and a short pulse of a high current during programming by a drain, such that a relatively lower voltage is used for operation.
